(19) United States
(12) Patent Application Publication
(10) Pub. No.: US 2026/0312419 A1
(43) Pub. Date: Oct. 8, 2026

(54) Charge/Discharge Control Device and Charge/Discharge Control Method

(71) Applicant: Astemo, Ltd., Chiyoda-ku, Tokyo (JP)

(72) Inventors: Naoki YONEYA, Tokyo (JP); Takashi OKADA, Hitachinaka-shi, Ibaraki (JP); Yuki OKUDA, Hitachinaka-shi, Ibaraki (JP)

(21) Appl. No.: 19/482,860

(22) PCT Filed: Apr. 17, 2024
(86) PCT No.: PCT/JP2024/015282

§ 371 Date: Nov. 10, 2025

(30) Foreign Application Priority Data
May 22, 2023 (JP) 2023-083620

(51) Int. Cl. H02J 7/84; B60L 58/16; G01R 31/36; G01R 31/392; H01M 10/42; H01M 10/44; H02J 3/32; H02J 7/90

(52) U.S. Cl. CPC H02J 7/84; B60L 58/16; G01R 31/3648; G01R 31/392; H01M 10/425; H01M 10/44; H02J 3/322; H02J 7/933; H01M 2010/4271

(57) ABSTRACT

Provided are a charge/discharge control device and a charge/discharge control method capable of ascertaining an influence of a battery deterioration factor accompanying charge/discharge and suppressing battery deterioration. A charge/discharge control device that controls charge/discharge of a storage battery connected to a load includes: means for setting a reference operation pattern of charge/discharge of the storage battery and calculating a reference deterioration amount that is a deterioration amount of the storage battery in the reference operation pattern; means for calculating an actual operation deterioration amount that is a deterioration amount of the storage battery in an actual operation pattern different from the reference operation pattern when charge/discharge of the storage battery is operated in the actual operation pattern; means for calculating a deterioration amount difference that is a difference between the reference deterioration amount and the actual operation deterioration amount; and means for calculating a contribution degree of each of a plurality of deterioration factors that are factors of deterioration of the storage battery based on the deterioration amount difference.

### TECHNICAL FIELD

The present invention relates to a charge/discharge control device and a charge/discharge control method.

### BACKGROUND ART

In a case of performing V2H (Vehicle to Home) that connects an electric vehicle EV to a house, V2G (Vehicle to G) that connects an electric vehicle to a power system, V2L (Vehicle to Load) that connects an electric vehicle to an electric load, V2V (Vehicle to Vehicle) that connects vehicles, or V2X (Vehicle to Everything) that collectively refers to the above techniques and connects an electric vehicle to any device that performs power transmission/reception, charge-discharge opportunities of a battery mounted on the electric vehicle EV increase, so that battery deterioration is likely to proceed.

The deterioration of the battery largely depends on an operation method. It is known that, even in a case where an operation with the same total charge/discharge amount is performed in the same temperature environment, the deterioration amount varies depending on a cycle depth indicating an increase/decrease rate of a state of charge (SOC) of the battery, an average SOC, a charging time, and the like. It is necessary to suppress, to the minimum, a decrease in battery health (SOH) (State of Health) by proper charge/discharge control while playing a role as a battery to be tested for V2X operation.

Conventionally, as a technique for estimating a relationship between a battery operation pattern and a state of health (SOH) in a case where an operation pattern is not uniform but sequentially varies as in V2X, there is a technique as disclosed in PTL 1 and PTL 2, for example.

PTL 1 discloses that a storage unit that stores a deterioration line indicating a correspondence relationship between a use amount of a battery and a full charge capacity of the battery for each use method of the battery is provided, the use method of the battery is determined, and in a case where it is determined that the use method is switched, the full charge capacity of the battery is estimated by offsetting the current deterioration line of the battery such that the full charge capacity of the deterioration line before the use method is changed coincides with the full charge capacity of the deterioration line after the use method is changed.

PTL 2 discloses that a prescribed current proportion distribution indicating a current proportion distribution when a vehicle travels in each of a plurality of traveling patterns set in advance is stored, and a traveling pattern proportion indicating a proportion of each prescribed current proportion distribution when an actual current proportion distribution is represented by a combination of a plurality of prescribed Current proportion distributions is derived based on the actual current proportion in actual operation and the prescribed current proportion distribution.

### CITATION LIST

### Patent Literature

PTL 1: JP 2020-159990 A

PTL 2: JP 2022-144152 A

### SUMMARY OF INVENTION

### Technical Problem

Even in a case where the operation pattern is not uniform and sequentially varies as in V2X, it is necessary to suppress, to the minimum, a decrease in battery health (SOH) (State of Health) by appropriate charge/discharge control while playing a role as a battery to be used as a power storage facility on a power network.

In the technique disclosed in PTL 1, it is necessary to prepare deterioration lines for a battery use method in advance as many as the number of assumed charge/discharge patterns, and it is difficult to cope with charge/discharge patterns having a wide variety of charge/discharge patterns from traveling to grid interconnection, like EVs to be tested for V2X.

In the technique disclosed in PTL 2, fitting with an actual complicated charge/discharge pattern is performed by superimposing the prescribed current proportion distributions indicating current proportion distributions when a vehicle travels in a plurality of respective preset traveling patterns, so that it is possible to cope with a wide traveling pattern with a finite pre-stored pattern. However, only a dominant traveling pattern can be seen from the obtained result, and it is difficult to obtain a guideline for suppressing battery deterioration.

As described above, the known patent literatures have a problem that it is not possible to ascertain the influence of a battery deterioration factor in a case where the operation pattern sequentially varies, and it is not possible to perform appropriate operation for suppressing battery deterioration for a long term.

In view of the above problems, an object of the present invention is to provide a charge/discharge control device and a charge/discharge control method capable of ascertaining an influence of a battery deterioration factor accompanying charge/discharge and suppressing battery deterioration.

### Solution to Problem

From the above description, in the present invention, “there is provided a charge/discharge control device that controls charge/discharge of a storage battery connected to a load, the charge/discharge control device including: means for setting a reference operation pattern of charge/discharge of the storage battery and calculating a reference deterioration amount that is a deterioration amount of the storage battery in the reference operation pattern; means for calculating an actual operation deterioration amount that is a deterioration amount of the storage battery in an actual operation pattern different from the reference operation pattern when charge/discharge of the storage battery is operated in the actual operation pattern; means for calculating a deterioration amount difference that is a difference between the reference deterioration amount and the actual operation deterioration amount; and means for calculating a contribution degree of each of a plurality of deterioration factors that are factors of deterioration of the storage battery based on the deterioration amount difference”.

In addition, in the present invention, “there is provided a charge/discharge control method for controlling charge/discharge of a storage battery connected to a load, with a computer, the charge/discharge control method including: by the computer, setting a reference operation pattern of charge/discharge of the storage battery and calculating a reference deterioration amount that is a deterioration amount of the storage battery in the reference operation pattern; calculating an actual operation deterioration amount that is a deterioration amount of the storage battery in an actual operation pattern different from the reference operation pattern when charge/discharge of the storage battery is operated in the actual operation pattern; calculating a deterioration amount difference that is a difference between the reference deterioration amount and the actual operation deterioration amount; and calculating a contribution degree of each of a plurality of deterioration factors that are factors of deterioration of the storage battery based on the deterioration amount difference”.

### Advantageous Effects of Invention

According to the present invention, it is possible to accurately and quantitatively ascertain a change in a battery deterioration factor due to a difference in an operation method, and it is possible to suppress battery deterioration by performing an operation of applying a load to a battery in a balanced manner.

### BRIEF DESCRIPTION OF DRAWINGS

FIG. 1 is a diagram illustrating an example of an overall configuration including a charging system when a vehicle is V2H-connected.

FIG. 2 is a diagram illustrating an example of an overall configuration including a charging system when a vehicle is V2H-connected via a stationary DC charger.

FIG. 3 is a diagram illustrating an example of a configuration of a charge/discharge control device according to Example 1 of the present invention.

FIG. 4 is a diagram illustrating a comparative example of a reference operation pattern and an evaluation target operation pattern.

FIG. 5 is a diagram illustrating an example of extraction of a deterioration factor.

FIG. 6 is a diagram illustrating an example of an input/output response of a battery deterioration model.

FIG. 7 is a diagram illustrating a base deterioration amount, a deterioration amount difference, and a contribution degree classification example.

FIG. 8 is a flowchart illustrating an example of a control method for a charge/discharge control device according to Example 2 of the present invention.

FIG. 9 is a diagram illustrating an example of waveforms of a current, a voltage, and an SOC when an operation is performed by fixing a battery operation pattern.

FIG. 10A is a graph showing an accumulation visualization result of the battery deterioration factor when the operation is performed by fixing the battery operation pattern.

FIG. 10B is a graph showing that a load related to a cycle depth is applied to a battery.

FIG. 11 is a diagram illustrating an example of waveforms of a current, a voltage, and an SOC when an operation is performed by periodically changing a battery operation pattern.

FIG. 12A is a graph showing an accumulation visualization result of the battery deterioration factor when the operation is performed by periodically changing the battery operation pattern.

FIG. 12B is a graph showing that three deterioration factors including the cycle depth, a charging time, and an SOC average value are applied to a battery.

### DESCRIPTION OF EMBODIMENTS

Hereinafter, embodiments for embodying the present invention will be described with reference to the accompanying drawings. In the present specification and the drawings, components having substantially the same functions or configurations are designated by the same reference signs, and repetitive description will be omitted.

### Example 1

Hereinafter, a charge/discharge control device according to an example of the present invention will be described. Note that, in the drawings, the common members are denoted by the same reference signs.

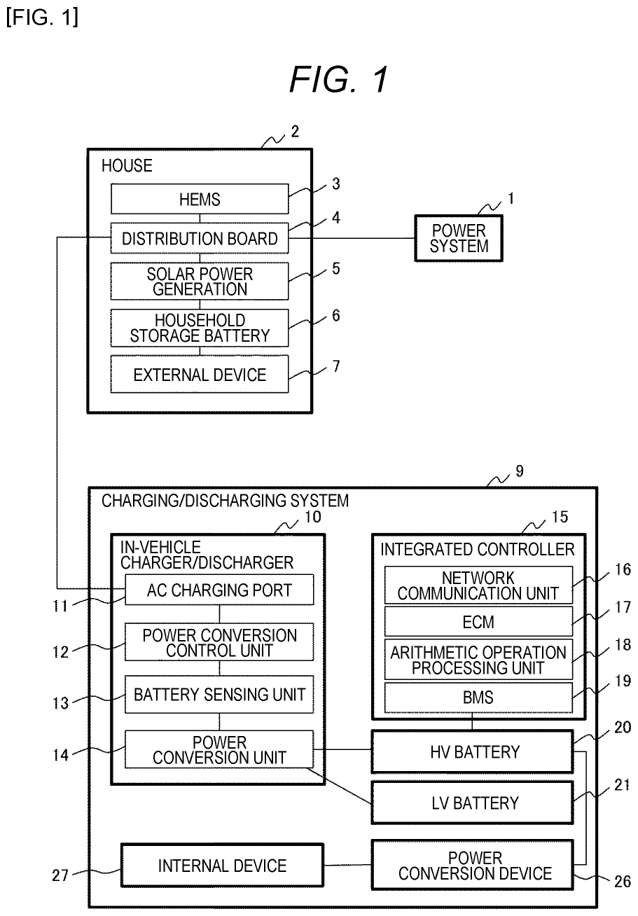

FIG. 1 is a hardware diagram of an overall configuration including a charging system when a vehicle is V2H-connected. In FIG. 1, power is supplied from a power system 1 to a home 2, and power is supplied from each home 2 to a vehicle 9 equipped with an in-vehicle charger/discharger 10.

Among these, each home 2 includes an HEMS 4, a distribution board 4, and an external device 7, and further includes a solar power generation facility 5 and a home storage battery 6 as appropriate. Note that, here, an example in which a vehicle 9 that is an electric vehicle or a plug-in hybrid vehicle is connected to the house 2 assuming a detached house will be described, but the house 2 is not necessarily limited to a detached house in which the owner of the vehicle 9 lives. For example, it may be an apartment house, or a facility corresponding to the house 2 may be a business place or a parking lot. A configuration in which a plurality of vehicles 9 are connected may be made. Note that the home 2 can be referred to as an external power source in a case of being viewed from, for example, an in-vehicle charger/discharger.

On the other hand, the vehicle 9 includes an in-vehicle charger/discharger 10, an comprehensive controller 15, a battery (HV battery 20, LV battery 21), a power conversion device 26, and an internal device 27 therein. Note that the in-vehicle charger/discharger 10 includes an AC charging port 11, a power conversion control unit 12, a battery sensing unit 13, and a power conversion unit 14 therein. The integrated controller 15 includes a network communication unit 16, an ECM 17, an arithmetic operation processing unit 18, and a battery management system (BMS) 19.

With the installation of such a device, a charging/discharging system of FIG. 1 charges the battery (HV battery 20, LV battery 21) mounted on the vehicle 9 with power supplied from an external power source (each home 2).

Hereinafter, main devices constituting the charging/discharging system will be described in detail. First, among the batteries, the HV battery 20 is mounted on the vehicle 9, and includes a battery module capable of realizing a desired output characteristic by connecting a plurality of battery cells in series or in parallel. Examples of the HV battery 20 include a lithium ion battery. The LV battery 21 is used for power supply or the like to an in-vehicle 12 V system device, and examples thereof include a lead-acid battery. The HV battery 20 is connected to the power conversion device 26, and the internal device 27 uses electric energy in a desired manner. The power conversion device 26 converts power discharged from the HV battery 20 into power and supplies the power to the internal device 27.

In order to be able to detect the state of the HV battery 20, the battery management system BMS 19 in the integrated controller 15 includes a voltage measurement unit capable of detecting the voltage of the battery cell, a current measurement unit capable of detecting the current flowing through the battery cell, and a temperature measurement unit that detects the temperature of the HV battery 20. The voltage measurement unit is configured in a form in which a voltage line is attached between the battery cells such that each terminal voltage of the battery cell can be individually measured. As the current measurement unit, for example, there is a method of detecting the current by measuring the voltage of a shunt resistor Rsht, and a sensor such as a Hall element can be used. A thermistor, a thermocouple, or the like can be used as the temperature measurement unit.

As described above, the BMS 19 detects the state of the HV battery 20 by converting the state into voltage information. Thus, the BMS 19 can be configured by a semiconductor device such as a general-purpose analog front-end IC or an ASIC (Application Specific Integrated Circuit). By providing an A/D converter, a result obtained by detecting a state amount of the HV battery 20 as a voltage can be converted into a digital value that can be used in arithmetic operation processing such as a program.

The power conversion device 26 is, for example, a bidirectional inverter, and thereby drives a traveling motor used for traveling of the vehicle 9. The bidirectional inverter includes a DC/DC converter unit and an inverter unit, the DC/DC converter unit voltage-converts a DC voltage of the HV battery 20 into a voltage necessary for driving the traveling motor, and the inverter unit converts DC power into AC power to perform frequency control according to a rotation speed of the traveling motor and power the traveling motor, thereby obtaining a rotational force (drive torque) for accelerating the vehicle. Alternatively, at the time of deceleration of the vehicle, regenerative driving is performed, kinetic energy of the vehicle is regenerated as electric power, and electricity is sent to the HV battery 20 via the DC/DC converter unit to charge the HV battery 20.

The internal device 27 is, for example, the above-described traveling motor, and accelerates the vehicle 9 by using electric power as a rotational force, and regenerates an inertial force of the vehicle 9 as electric power by driving the traveling motor as a power generator in cooperation with the bidirectional inverter while the vehicle 9 is traveling.

In order to realize such an operation, the power conversion device 26 includes a controller (not illustrated), and adjusts an output voltage of the DC/DC converter unit by controlling a duty ratio of a switching element of the DC/DC converter unit, and adjusts a driving force of the traveling motor by adjusting a switching frequency and a current phase of the inverter unit. The internal device 27 is provided with various sensors for the power conversion device 26 to control the internal device 27 in a desired manner.

The power conversion device 26 is also an inverter different from, for example, the bidirectional inverter for driving the traveling motor described above, and the internal device 27 is also a compressor driving motor. As a result, an air conditioner for air-conditioning the passenger compartment of the vehicle 9 is driven.

That is, the power conversion device 26 and the internal device 27 are means for consuming the power of the HV battery 20, in other words, one of means for discharging the power of the HV battery 20, and the vehicle 9 is provided with a plurality of power conversion devices 26 and internal devices 27. In addition, the HV battery 20 is connected to the in-vehicle charger/discharger 10 and a DC charging port.

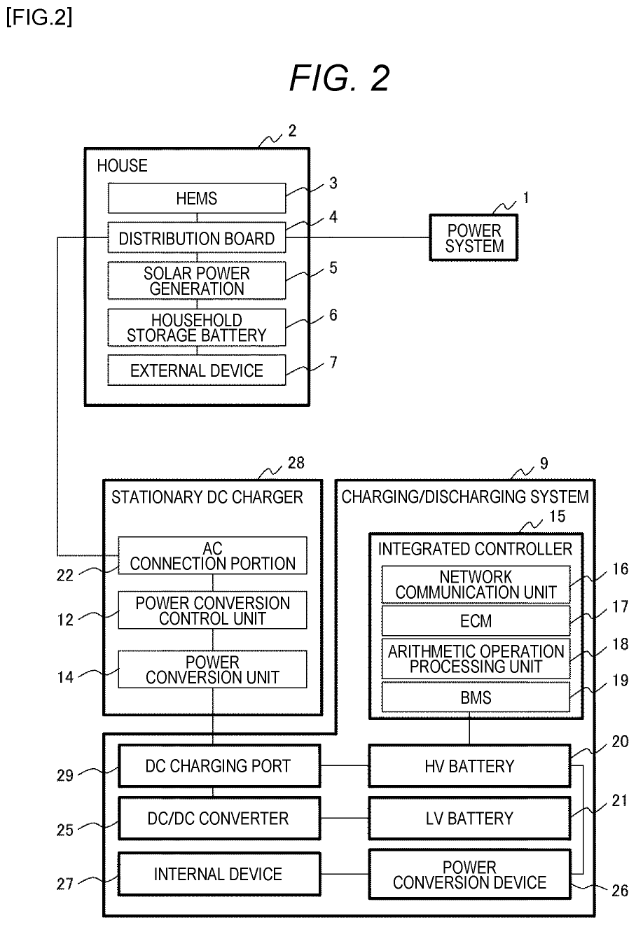

Although FIG. 1 illustrates an example in which the in-vehicle charger/discharger 10 is mounted on the vehicle with a charging function, it is also possible to adopt a system in which a charging/discharging function is not mounted on the vehicle. FIG. 2 is a hardware diagram of an overall configuration in a case where the charging function is not mounted on the vehicle. As is clear from comparison between FIG. 1 and FIG. 2, in FIG. 2, a part of the functions of the in-vehicle charger/discharger 10 is separated as a stationary DC charger 28, and a DC charging port 29 and the DC-DC converter 25 are newly installed in the vehicle. It can be said that this difference is due to a difference in charging method between AC charging in FIG. 1 and DC charging in FIG. 2.

As described above, the present invention can cope with AC charging via the AC charging port 11 of the in-vehicle charger/discharger 10 and DC charging via the stationary charger 28 and the DC charging port 29 illustrated in FIG. 2, as a charging method of the charging/discharging system of the vehicle 9. AC charging and DC charging are exclusively used by a relay or a semiconductor switch (not illustrated) in the in-vehicle charger/discharger 10. The in-vehicle charger/discharger 10 is mounted on the vehicle 9, and bidirectionally power-converts power supplied from an external power source such as the house 2 and power discharged from the HV battery 20. A stationary charger 101 is installed outside the vehicle 9 and the house 2, and bidirectionally power-converts power supplied from a power source such as the house 2 and power discharged from the HV battery 20.

In AC charging, the in-vehicle charger/discharger 10 is further connected to a charging cable via the AC charging port 11, and the charging cable is connected to the distribution board 4 of the house 2. A connection method to the distribution board 4 may be direct connection via a leakage circuit breaker or connection via an AC outlet of the house 2. The distribution board 4 is electrically connected to an ampere breaker (not illustrated) and a power meter power system 1.

In DC charging, an AC-DC power conversion unit of the stationary charger 28 is connected via the DC charging port 26, and the stationary charger 101 is connected to the distribution board 4 in the house 2. Thereafter, similarly to the AC charging, electrical connection is performed up to the power system 1.

The in-vehicle charger/discharger 10 includes a DC/DC converter unit capable of transforming a DC voltage and converting the DC voltage into an AC voltage, and a power conversion unit 14 having an inverter unit capable of rectifying AC power from the distribution board 4 into DC power and converting the DC power output from the DC/DC converter unit into AC power. In addition, the power conversion control unit 12 that controls these components, the AC charging port 11 that connects AC power, and the battery sensing unit that measures battery data from these currents are included.

Similarly to the in-vehicle charger/discharger 10, the stationary charger 28 also includes a power conversion unit 14 and a power conversion control unit 12.

When the HV battery 20 is charged, so-called CC-CV (Constant Current, Constant Voltage) charging obtained by combining constant current charging and constant voltage charging corresponding to the battery cells in the HV battery 20 is performed.

Specifically, in a state where the charging rate of the HV battery 20 is low, constant current charging is performed, and the charging speed is adjusted such that the current flowing through the battery cell in the HV battery 20 does not become a predetermined value or more. When an excessive current flows through the battery cell, lithium ions are not taken in between negative electrode active material layers in the battery cell, and lithium metal is precipitated on the negative electrode, thereby causing an internal short circuit, which may lead to thermal runaway accompanied by ignition or rupture of the battery cell. In order to prevent this situation, it is necessary to control the charging speed, that is, the current so that an excessive current does not flow.

When the charging of the HV battery 20 progresses and the voltage of the battery cell increases, the process shifts to constant voltage charging. When the voltage of the battery cell is excessively increased, lithium ions are extracted from a positive electrode active material, the electrode structure becomes brittle, and the reactivity of the positive electrode is increased, so that the decomposition reaction of the electrolytic solution proceeds to generate a gas in the battery cell, and the decomposition reaction of an electrolytic solution also proceeds to generate heat. Since the gas and the electrolytic solution generated in the battery cell are flammable, the gas and the electrolytic solution may ignite to cause destruction such as ignition of the battery cell or rupture due to an increase in gas pressure. Similarly to the current, it is necessary to control the voltage so as not to become an excessive voltage.

When the in-vehicle charger/discharger 10 is taken as an example, the power conversion unit 14 rectifies AC power obtained through the AC charging port 11 into DC power, and controls the duty ratio of the switching element of the DC/DC converter unit inside the power conversion unit 14, thereby controlling the charging current and the charging voltage flowing to the battery cell and eventually the HV battery 20. Similarly, in the stationary charger 28, the power conversion unit 14 rectifies the AC power obtained through the distribution board 4 into DC power, and controls the duty ratio of the switching element of the DC/DC converter unit inside the power conversion unit 14, thereby controlling the charging current and the charging voltage flowing to the battery cell and eventually the HV battery 20.

As described above, the HV battery 20 can be charged by the in-vehicle charger/discharger 10 and the stationary charger 28.

In a case where the power of the HV battery 20 is supplied to the house 2, the DC/DC converter unit of the power conversion unit 14 of the in-vehicle charger/discharger 10 adjusts the voltage according to the AC power used in the house 2.

The inverter unit of the power conversion unit 14 generates an alternating current so that the frequency and the phase of the AC power used in the house 2 are synchronized. The power control conversion control unit 12 adjusts the duty ratio of a switching signal to be commanded to the switch element of the DC/DC converter unit for voltage adjustment, and also adjusts a switching command of the inverter unit so as to feed back the frequency and the phase of the AC power in the house 2 and synchronize the frequency and the phase in order to send power to the house 2.

The same applies to a case where the power of the HV battery 20 is supplied to the house 2 through the stationary charger 28, and the DC/DC converter unit of the power conversion unit 14, the inverter unit, and the power conversion control unit 12 are operated like the DC/DC converter unit of the power conversion unit 14, the inverter unit, and the power conversion control unit 12 of the in-vehicle charger/discharger 10.

By allowing the power of the HV battery 20 to be used in the house 2 through the in-vehicle charger/discharger 10 and the stationary charger 28, for example, it is possible to use the power of the HV battery 20 in a case where there is no power supply from the power system 1 at the time of disaster, or to reduce the amount of power purchased from the power system 1 to reduce the electric bill of the house 2.

The house 2 may further include a solar power generation system 5 or a fuel cell system (not illustrated) as a power source to replace the power system 1.

In addition to the solar power generation system 5 described above, the external device 7 is connected to the distribution board 4 of the house 2. The external device 7 is a house facility of the house 2 or a so-called electric appliance, and examples thereof include an air conditioner for conditioning the house 2, a hot water supply system, lighting, a cooking appliance, a refrigerator, a white appliance such as a washing machine, a black appliance such as a television and an audio, and an information appliance such as a personal computer and a telephone.

Supplying the power of the HV battery 20 to the house 2 via the in-vehicle charger/discharger 10 or the stationary charger 28 means consuming the power of the HV battery 20, in other words, is one of other means for discharging the power of the HV battery 20.

The house 2 includes the home power management system HEMS (Home Energy Management System) 3, and can adjust the water boiling timing of the hot water supply system as the external device 111 according to the operation state and the power generation amount of the solar power generation system 5 and the hot water supply system as the external device 111, and perform the operation state of the air conditioner as the external device 111, power selling of the surplus power of the solar power generation system 5 to the power system 1, and the like according to the power demand of the house 2 acquired from the power meter. The HEMS 3 may be configured to be able to query the power demand of the house 2 from the outside via a communication module (not illustrated), and the integrated controller 27 of the vehicle 9 may be configured to be able to acquire information such as the power demand of the house 2 held by the HEMS 3 through the network communication unit 16 of the vehicle 9.

The integrated controller 15 includes, as functional blocks, the network communication unit 16, the engine control module (ECM) 17, the arithmetic operation processing unit 18, and the battery management system (BMS). Details of the operation of each functional block of the integrated controller 15 will be described later.

The arithmetic operation processing unit 18 of the integrated controller 15 includes an arithmetic operation unit including a CPU and the like, and a storage unit including a memory such as a RAM and a ROM, a recording medium, and the like, and realizes each functional block of the integrated controller 15 by executing a program stored in the storage unit.

The integrated controller 15 is configured to be able to acquire the operating states of the power conversion device 26 and the internal device 27 and the state of the HV battery 20 as necessary, and to be able to communicate with the stationary charger 28 through the DC charging port 29. The integrated controller 15 can also communicate via the AC charging port 11 and the charging cable. A communication method such as a CAN (Controller Area Network) or a LIN (Local Interconnect Network), Ethernet connection, or the like can be used for communication between the vehicle 9 and the house 2, and there is no problem even if the CAN or the LIN is used in the vehicle 9 and communication using Ethernet is used for communication in the house 2. In addition, communication by PLC (Power Line Communication) or the like may be used. Not only wired communication but also wireless communication may be performed.

The configuration case of the charging/discharging system to which the present invention can be applied has been described above with reference to FIGS. 1 and 2. Next, a case where the vehicle 9 is stopped and charging is performed from an external power source will be examined.

As described above, the known charging method has a problem that it is not possible to ascertain the influence of the battery deterioration factor in a case where the operation pattern sequentially varies, and it is not possible to perform appropriate operation for suppressing battery deterioration for a long term. Therefore, here, a method for ascertaining an influence of a battery deterioration factor accompanying charge/discharge and a deterioration suppressing method in the charge/discharge control device of the present invention will be described.

In the battery deterioration in the cell of the HV battery 20, the deterioration progresses mainly by the structural change of a positive electrode and a negative electrode due to charge/discharge cycle performing. For example, the negative electrode formed of a graphite material deteriorates due to repeated expansion and contraction accompanying the use environment and charge/discharge. In addition, the positive electrode formed of a ternary metal material or the like also deteriorates due to metal corrosion, elution of a binder component, or the like. At this time, when the same charge/discharge cycle is repeatedly performed in a V2G operation pattern, it is considered that there is a concern of causing an increase in the specific deterioration form and local deterioration in the cell. When a specific part in the battery is completely destroyed, the state of health (SOH) of the battery decreases even if other parts are healthy, and the battery cannot be used. Although it is necessary to avoid local deterioration inside the battery, it is difficult to individually control a deterioration part inside the battery, and thus, the burden on the battery is uniformized by using an operational deterioration factor as an evaluation index.

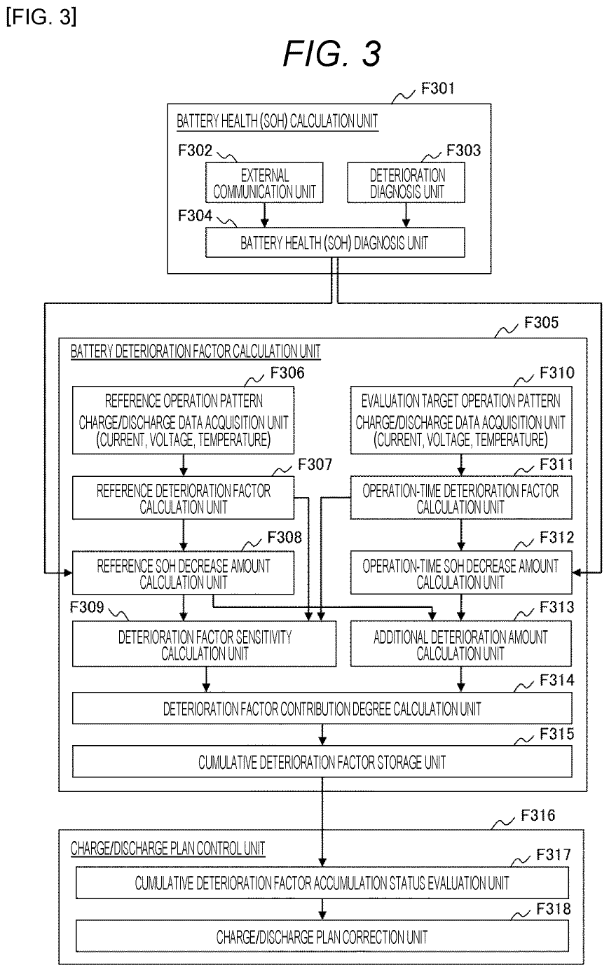

FIG. 3 is a diagram illustrating an example of the configuration of the charge/discharge control device according to Example 1 of the present invention. The charge/discharge control device according to Example 1 of the present invention is realized by, for example, the arithmetic operation processing unit 18 in the comprehensive controller 15 in FIGS. 1 and 2, or is configured on a cloud, and a processing result thereof is stored and used in the comprehensive controller 15 via the network communication unit 16. Note that, in the following description, realization by the arithmetic operation processing unit 18 will be described as an example.

The processing of the charge/discharge control device is generally realized by using a computer, but when the processing content in the arithmetic operation unit is represented as a processing function, as illustrated in FIG. 3, the charge/discharge control device includes processing functions of a battery health (SOH) calculation unit F301, a battery deterioration factor calculation unit F305, and a charge/discharge plan control unit F316.

The battery health (SOH) calculation unit F301 includes an external communication unit F302 that acquires a deterioration status of the vehicle battery from a deterioration diagnosis device or the like outside the vehicle such as the stationary charger 28, a deterioration diagnosis unit F303 that acquires a battery deterioration status from a deterioration diagnosis device of the vehicle the in-vehicle charger/discharger 10, and a battery health (SOH) diagnosis unit F304 that estimates battery health (SOH) based on these pieces of information.

The battery deterioration factor calculation unit F305 quantifies the battery deterioration amount and the contribution degree of the deterioration factor when the battery is charged and discharged in accordance with a certain evaluation target operation pattern. When a difference in the deterioration amount due to two charge/discharge patterns is evaluated, most of the deterioration amount is occupied by the reference deterioration amount commonly generated regardless of the operation difference. Therefore, there is a problem that the daily deterioration amount difference due to the operation difference is very small, and the contribution degree calculation described later cannot be accurately performed when the deterioration amount of the evaluation target operation pattern is directly evaluated.

Therefore, in the present invention, the reference operation pattern and the reference deterioration amount are defined, and the difference from the deterioration amount in the evaluation target operation pattern is taken, thereby improving the extraction accuracy of the change in the battery deterioration factor due to the operation difference.

Among these, processing of F306, F307, and F308 is performed for the reference operation pattern. Specifically, a reference operation pattern charge/discharge data acquisition unit F306 in FIG. 3 acquires the current, the voltage, and the temperature history in the reference operation pattern. Then, a reference deterioration factor calculation unit F307 extracts a feature amount related to battery deterioration from charge/discharge data, and a reference health (SOH) decrease amount calculation unit F308 calculates a battery health (SOH) decrease amount at the time of the reference operation by using the feature amount as an input and a battery deterioration model. Details of the calculation of the feature amount and the health (SOH) decrease amount regarding the battery deterioration will be described later.

Similarly, processing of F310, F311, and F312 is performed for the evaluation target operation pattern. Specifically, an evaluation target operation pattern charge/discharge data acquisition unit F310 in FIG. 3 acquires the current, the voltage, and the temperature history in the evaluation target operation pattern. Then, an operation-time deterioration factor calculation unit F311 extracts a feature amount related to battery deterioration from the charge/discharge data, and an operation-time health (SOH) decrease amount calculation unit F312 calculates a battery health (SOH) decrease amount during the evaluation target operation by using the feature amount as an input.

Then, an additional deterioration amount calculation unit F313 calculates an additional deterioration amount caused by the operation difference by taking the difference between the battery health (SOH) decrease amounts in the reference operation pattern and the evaluation target operation pattern.

Then, a deterioration factor sensitivity calculation unit F309 calculates the sensitivity of the deterioration factor by using gradient information of the battery deterioration model used for calculation of the health (SOH) decrease amount. The details will be described later. A contribution degree calculation unit F314 of the deterioration factor quantifies the contribution degree of the deterioration factor by using the additional deterioration amount and the deterioration factor sensitivity described above. A cumulative deterioration factor storage unit F315 accumulates and stores the calculated deterioration factor contribution degree.

In the charge/discharge plan control unit F316, a cumulative deterioration factor accumulation status evaluation unit F317 confirms whether or not there is no deterioration accumulation biased to a specific factor in the accumulated and stored deterioration factors. A charge/discharge plan correction unit F318 corrects a charge/discharge plan to avoid biased accumulation of deterioration factors.

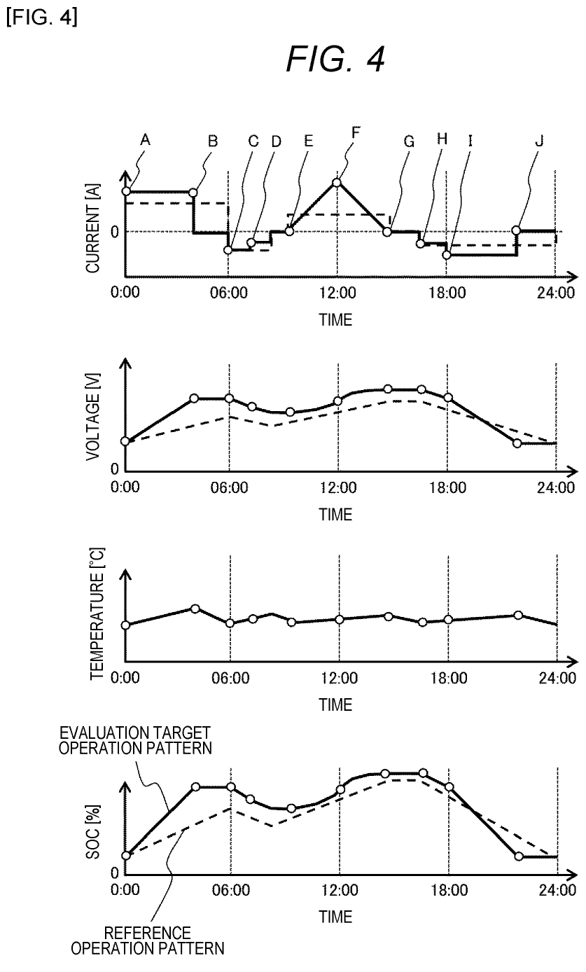

A comparative example of the reference operation pattern and the evaluation target operation pattern will be described with reference to FIG. 4. In FIG. 4, the horizontal axis indicates 24 hours in a day and the vertical axis indicates the magnitudes of the current, the voltage, the temperature, and the SOC sequentially from the top. The time-series change in the magnitudes of the current, the voltage, the temperature, and the SOC in the reference operation pattern is indicated by a dotted line, and the time-series change in the magnitudes of the current, the voltage, the temperature, and the SOC in the evaluation target operation pattern is indicated by a solid line. However, regarding the current, the positive direction indicates charging of the battery, and the negative direction indicates discharging to the home side. Note that, for simplification, a CV charging curve of CCCV charging in the current profile is not described.

According to the case of FIG. 4, in the evaluation target operation pattern indicated by the solid line, power is purchased at night from the point A at 0:00 at midnight, and the vehicle 9 is charged. Then, at the point B, the SOC reaches a charge upper limit, and the charge is stopped. Thereafter, the power supply to the house 2 is not performed until 6:00 in the morning, and the current value becomes zero. From the point c at 6:00 in the morning, the power consumption of heating and cooking appliances in the house 2 increases, and thus power is supplied from the vehicle 9 to the house 2. A driver of the vehicle 9 departs from the point D to the workplace or the like, and electricity of the HV battery 20 is consumed by traveling. After the vehicle 9 has finished traveling, the vehicle 9 arrives at the workplace or the house 2, and the connection to the power line is made again. From the point E, charging of power generated by the solar power generation 5 is started. The power generation amount by the solar power generation varies depending on the season, the weather, and the region, but the power generation amount is the maximum at the point F around noon. Thereafter, as it approaches the evening, the solar altitude decreases, the sunlight amount to the panel of the solar power generation 5 of the workplace or the house 2 decreases, and the charging current becomes zero at the point G. Thereafter, at the point H, the driver drives the vehicle from the workplace and returns home, and from the point I, discharging is performed to correspond to a peak of power consumption during the evening and the nighttime in the house 2. The discharging is performed until the battery SOC reaches a predetermined SOC lower limit value, and the charging current becomes zero at the point J.

In addition, according to the case of FIG. 4, the reference operation pattern of the dotted line is defined as a representative operation pattern in V2G, and the current profile is set on the premise of the event as described above.

The reference operation pattern does not necessarily need to be similar to the evaluation target operation pattern. In addition, the reference operation pattern does not need to be an actual measurement value, and a result analyzed by simulation may be used.

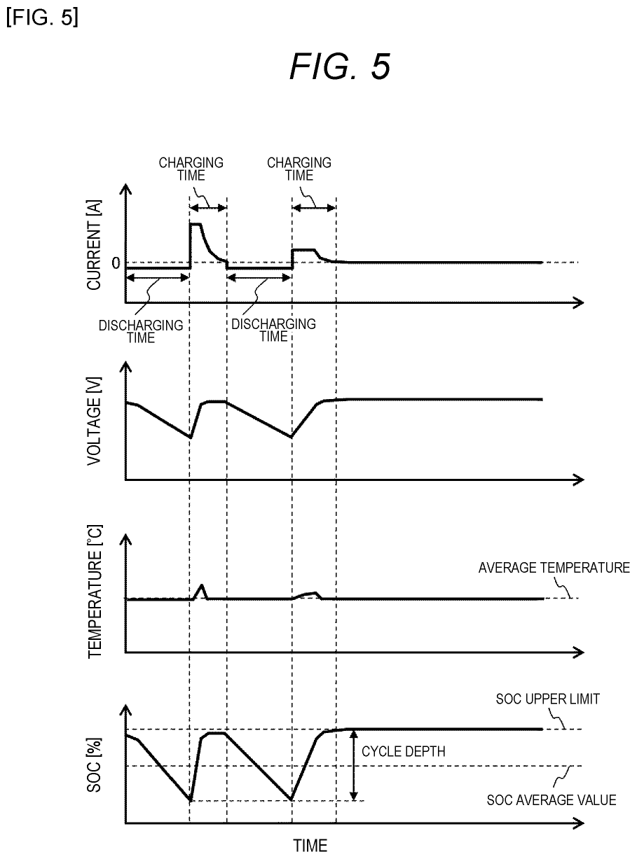

Next, extraction of the feature amount related to battery deterioration will be described. FIG. 5 is a diagram illustrating an example of extraction of the deterioration factor. Also in FIG. 5, similarly to FIG. 4, the horizontal axis indicates 24 hours in a day and the vertical axis indicates the magnitude of the current, the voltage, the temperature, and the SOC in order from the top. Here, the SOC can be calculated by taking time-series data of the current, the voltage, and the temperature as the charge/discharge data of the HV battery 20 and making the battery capacity at that time known. From the data, a deterioration factor parameter is extracted as an input parameter of the battery deterioration model.

Here, as an example of the deterioration factor parameter, the charging time that is a period during which the current value is positive, the discharging time that is a period during which the current value is negative, the battery average temperature, the cycle depth in which the increase/decrease amount of the SOC is calculated, the SOC upper limit value, and the SOC average value are defined.

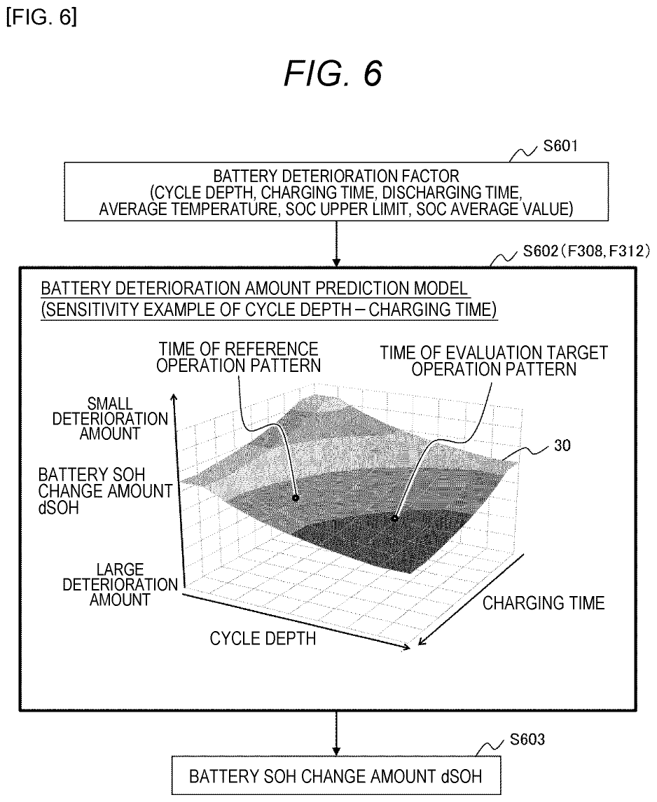

Next, calculation of the health (SOH) decrease amount and the deterioration factor sensitivity by the battery deterioration model will be described. FIG. 6 is a diagram illustrating an example of an input/output response of the battery deterioration model. Processing using the battery deterioration model is performed by the reference SOH decrease amount calculation unit F308 and the operation-time SOH decrease calculation unit F312 in FIG. 3. In processing step S601, the battery deterioration factor extracted from the charge/discharge data of the HV battery 20 is prepared as an input parameter. Then, in processing step S602, a battery health (SOH) decrease amount obtained by the operation is calculated by using the battery deterioration prediction model. Then, in processing step S603, a battery health (SOH) change amount (dSOH) is obtained.

Here, the battery deterioration model may be a database using a result of a charge/discharge test using an actual battery, or may be a simulation model. The battery deterioration model in this example is a multivariable function with six input parameters, but these parameters are factors that affect cycle deterioration of the battery, and the deterioration caused by these input factors has a relatively small nonlinear behavior, and when two parameters are used to indicate a relationship with the health (SOH), a response curved surface 30 of a smooth battery deterioration prediction value as illustrated in FIG. 6 is drawn. Note that FIG. 6 illustrates an example of a battery deterioration model in two cases where the input parameters are the discharging time and the cycle depth, and a relationship among the discharging time, the cycle depth, and the battery health (SOH) change amount dSOH is three-dimensionally defined as the battery deterioration model. The battery deterioration model expresses a difference between the time of the reference operation pattern and the time the evaluation target operation pattern.

Here, when the response curved surface 30 of the battery deterioration prediction value is partially differentiated with respect to each deterioration factor, a partial differential coefficient with respect to each factor is obtained. The partial differential coefficient corresponds to the gradient of the response curved surface, and the larger the gradient, the higher the degree of influence of the deterioration degree by the deterioration factor. Therefore, the contribution degree for each deterioration factor is quantified by distributing the deterioration amount difference due to the operation based on the ratio of the gradient of each deterioration factor.

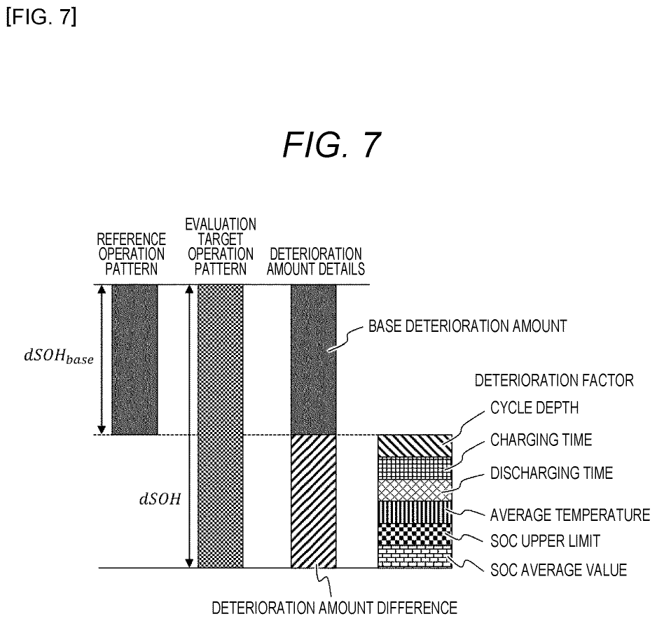

FIG. 7 is a diagram illustrating a base deterioration amount, the deterioration amount difference, and the contribution degree classification example. The base deterioration amount dSOHbase in the reference operation pattern on the left side of FIG. 7 is used as a reference, and the deterioration amount dSOH in the evaluation target operation pattern is indicated on the right side thereof. The present invention focuses on a deterioration amount difference obtained by taking a difference between the deterioration amount dSOH and the base deterioration amount dSOHbase.

In addition, the magnitude of the degree of influence is quantified for each deterioration factor (charging time, discharging time, battery average temperature, cycle depth, soc upper limit value, and SOC average value) that is a factor of an occurrence of the deterioration amount difference. By quantifying the magnitude of the degree of influence based on the gradient ratio of the response curved surface 30 in FIG. 6, it is possible to extract the deterioration amount due to an operation difference with high accuracy and quantify the magnitude of the degree of influence for each deterioration factor.

Note that when rapid charging is performed such that the charging current exceeds 1 C (1 C is a current value at which the capacity of the HV battery 20 can be fully charged in 1 hour), nonlinear deterioration such as lithium deposition may occur in the battery, and a maximum value or a minimum value may be generated on the response curved surface 30 of the battery deterioration model. In order to take into account the influence of rapid charging, it is desirable to separately prepare a deterioration model for rapid charging by using a peak current value at the time of charging, a time integral value thereof, and the like as input values, and correct the response curved surface 30 of the battery deterioration model.

### Example 2

In Example 1, the charge/discharge control device has been described, but in Example 2, a charge/discharge control method will be described.

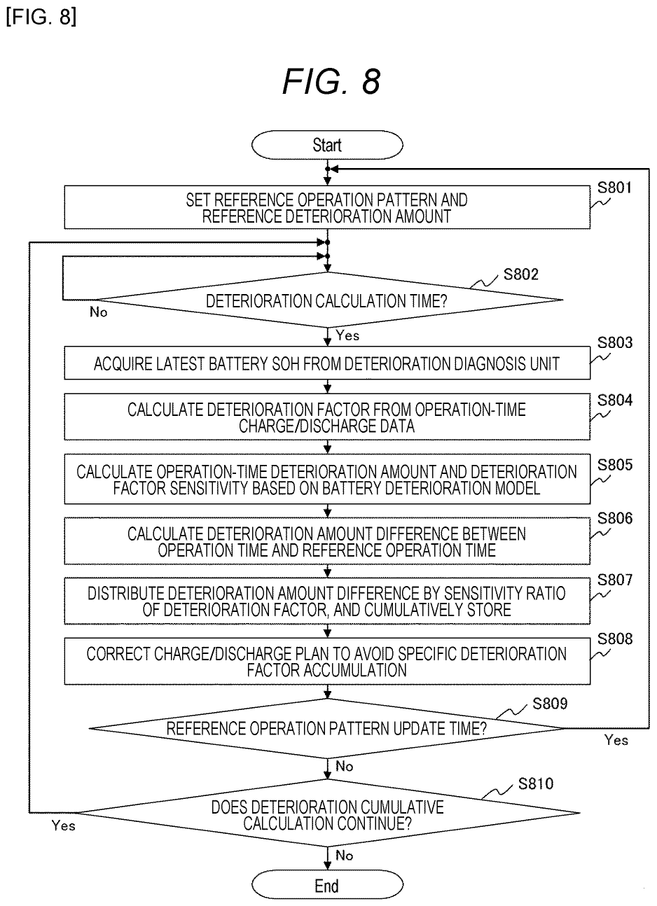

FIG. 8 is a flowchart illustrating an example of a control method for a charge/discharge device according to Example 2 of the present invention. In this processing, first, in processing step S801, a reference operating condition and a reference deterioration amount serving as a base are calculated. This base condition is appropriately updated when the vehicle owner changes or at a timing when the driving style of the driver changes.

In processing step S802, it is determined whether or not it is time to perform deterioration diagnosis. The deterioration diagnosis is performed at midnight 0:00 or the like. In a case where the deterioration diagnosis is performed, deterioration calculation using the operation data of the day is started. Specifically, in processing step S803, the deterioration status of the own vehicle battery is acquired from a deterioration diagnosis device or the like outside the vehicle such as the stationary charger 28, or the battery deterioration status is acquired from a deterioration diagnosis device of the own vehicle such as the in-vehicle charger/discharger 10.

Then, in processing step S804, a deterioration factor is calculated from the operation-time charge/discharge data (current, voltage, temperature, and SOC). In processing step S805, the operation-time deterioration amount and the deterioration factor sensitivity are calculated based on the battery deterioration model. In processing step S806, the deterioration amount difference between the operation time and the reference operation time is calculated by using output information of the deterioration model. Then, in processing step S807, the deterioration amount difference is distributed by the sensitivity ratio of the deterioration factors, and the deterioration factors are quantified and cumulatively stored.

Finally, in processing step S808, the next and subsequent charge/discharge plans are corrected to avoid accumulation of specific deterioration factors. In processing step S809, it is determined whether or not to update the reference operation pattern, and in processing step S810, it is determined whether or not to continue the deterioration accumulation calculation.

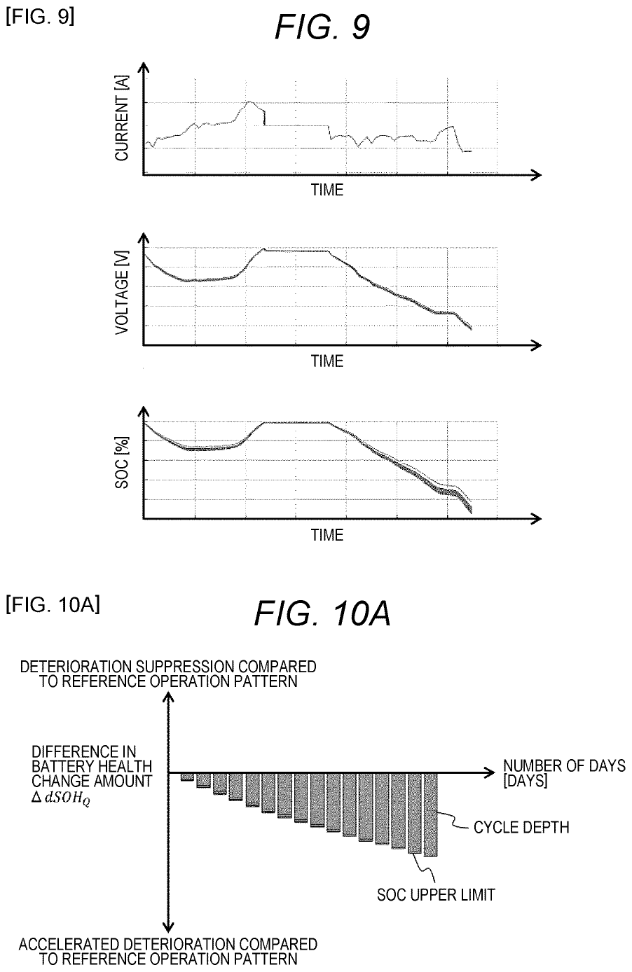

FIG. 9 is an example illustrating simulation waveforms of the current, the voltage, and the SOC when the operation is performed by fixing the battery operation pattern. A charge/discharge pattern was created assuming a V2G environment in which the vehicle 9 and the house 2 were connected. Starting from the fully charged state, discharging toward the home is first performed from time zero. Then, charging by solar power generation is performed. However, the SOC reaches the upper limit during charging, and charging is stopped during that time. Then, in the latter half, discharging toward the house 2 was performed. In this example, the same charge/discharge pattern was repeatedly performed for 30 days.

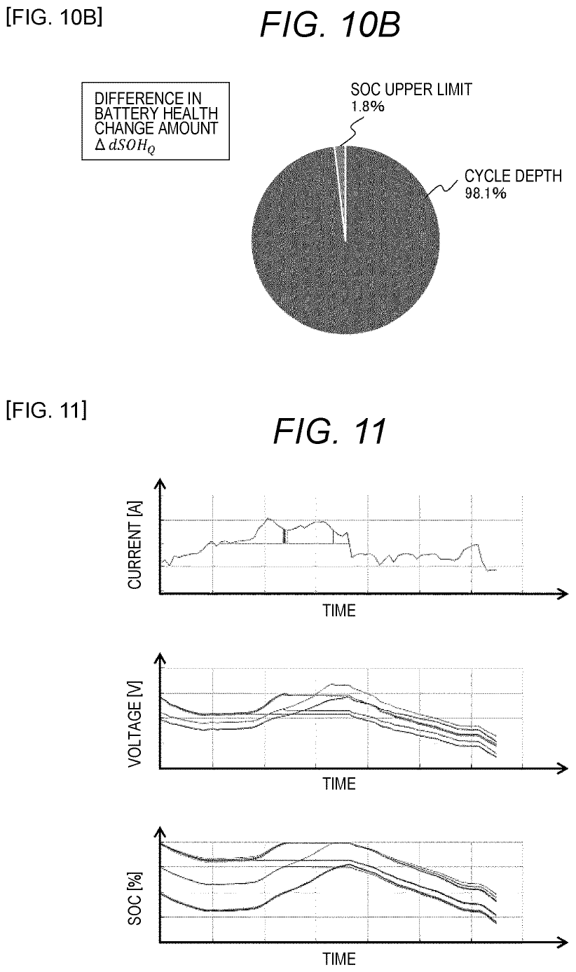

FIG. 10A is a graph showing an accumulation visualization result of the battery deterioration factor when the operation is performed by fixing the battery operation pattern. When the accumulation of deterioration factors is calculated based on the method in the present invention, a form in which the influence of the cycle depth is dominant at 98.1% and the influence is expanding is viewed. This indicates that the battery capacity decreases due to deterioration of the battery cell, and the change amount of the battery SOC for each charge/discharge increases by performing the same charge/discharge pattern regardless of the decrease in the battery capacity, and a load related to the cycle depth is applied to the battery as illustrated in FIG. 10B.

FIG. 11 is an example of waveforms of the current, the voltage, and the SOC when the operation is performed by periodically changing the battery operation pattern. In this case, a charge/discharge plan is made to periodically change the upper limit SOC at the time of charging and discharging and the lower limit SOC at the time of discharging, and it can be seen that the time history changes of the voltage and the SOC are diverse.

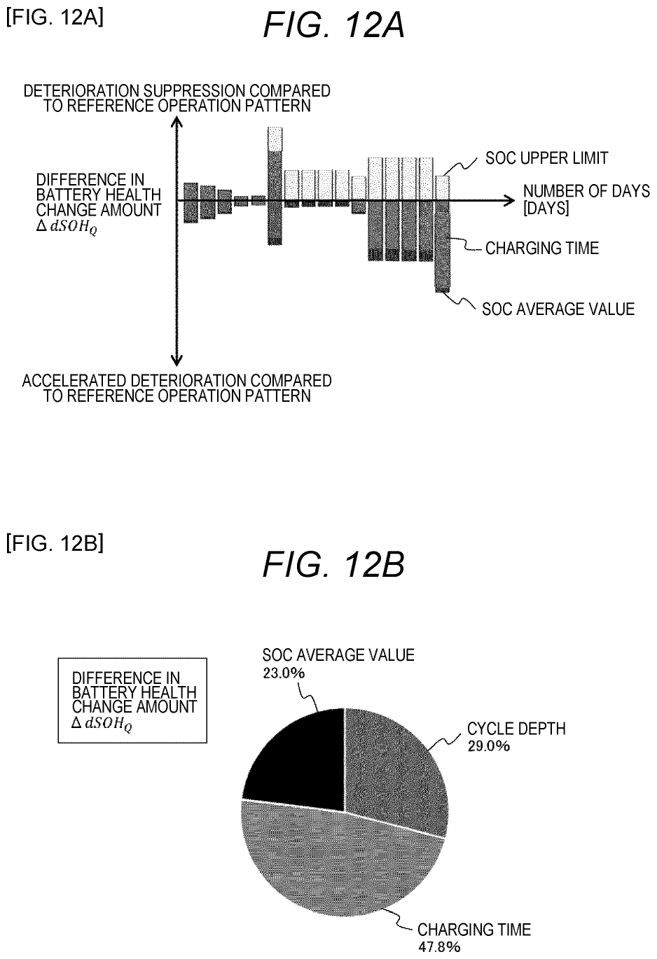

FIG. 12A is a graph showing an accumulation visualization result of battery deterioration factors when the operating is performed by periodically changing the battery operation pattern, according to the first embodiment of the present invention. By changing the battery operation pattern halfway (changing the actual operation pattern on the next and subsequent times to avoid accumulation of specific deterioration factors), the type and degree of influence of the accumulated deterioration factors are changed, and as illustrated in FIG. 12B, three deterioration factors of the cycle depth, the charging time, and the soc average value are applied to the battery. As described above, the charge and discharge control is performed such that the deterioration factors are uniformly accumulated without being biased to the specific factor, whereby the deterioration of the battery can be suppressed.

The notification of the visualization result Of the deterioration factors of the battery as illustrated in FIGS. 10A and 12A may be performed through an in-vehicle display, a smartphone owned by the driver, or the like. Further, by notifying the recommended charge/discharge pattern together, a user can be urged to connect the vehicle 9 to the electrical system in an appropriate time section, and ideal charge/discharge control for the vehicle 9 can be easily performed, and the utilization rate of the in-vehicle battery resources can be increased.

In the present example, the lithium ion battery has been described as an example, but the present invention can also be applied to various batteries such as all-individual batteries. Similar deterioration factor visualization and charge/discharge control can be applied to LV batteries such as lead-acid batteries.

In the present example, the factors illustrated in FIG. 5 are used as the deterioration factors, but a traveling distance of an automobile, a traveling time, an integrated value of vehicle vibration, and the like can also be used as the deterioration factors. In addition, the battery deterioration model may obtain the latest information of the battery by wired or wireless extra-vehicular communication, and modify or change the model used for deterioration. Furthermore, it is also possible to share model information between batteries of a specific production lot by using inter-vehicle communication, and to improve accuracy.

Note that it should be noted that the present invention is not limited to the above-described examples, and it goes without saying that various other application examples and modification examples can be taken as long as the gist of the present invention described in the claims is not deviated.

For example, the above-described embodiment describes the configurations of the device in detail and concretely in order to describe the present invention in an easy-to-understand manner, and is not necessarily limited to those including all the described constituent elements. Regarding some components in the present examples, other components can also be added, deleted, and replaced.

Control lines and information lines considered necessary for the descriptions are illustrated, and not all the control lines and the information lines in the product are necessarily shown. In practice, it may be considered that almost all components are connected to each other.

### REFERENCE SIGNS LIST

1 power system
2 house
3 HEMS
4 distribution board
5 solar power generation
6 household storage battery
7 external device
9 vehicle (electric vehicle or plug-in hybrid vehicle)
10 in-vehicle charger/discharger
11 AC charging port
12 power conversion control unit
13 battery sensing unit
14 power conversion unit
15 integrated controller
16 network communication unit
17 ECM
18 arithmetic operation processing unit
19 battery management system
20 HV battery (high voltage)
21 LV battery (low voltage)
22 AC connection portion
25 DC/DC converter
26 power conversion device
27 internal device
28 stationary DC charger
29 DC charging port
30 response curved surface of battery deterioration prediction value

1. A charge/discharge control device that controls charge/discharge of a storage battery connected to a load, the charge/discharge control device comprising:
means for setting a reference operation pattern of charge/discharge of the storage battery and calculating a reference deterioration amount that is a deterioration amount of the storage battery in the reference operation pattern;
means for calculating an actual operation deterioration amount that is a deterioration amount of the storage battery in an actual operation pattern different from the reference operation pattern when charge/discharge of the storage battery is operated in the actual operation pattern;
means for calculating a deterioration amount difference that is a difference between the reference deterioration amount and the actual operation deterioration amount; and
means for calculating a contribution degree of each of a plurality of deterioration factors that are factors of deterioration of the storage battery based on the deterioration amount difference.

2. The charge/discharge control device according to claim 1, further comprising means for changing a subsequent actual operation pattern to avoid accumulation of a specific deterioration factor among the plurality of deterioration factors.

3. The charge/discharge control device according to claim 1, wherein the reference operation pattern and the reference deterioration amount are calculated or recorded based on a battery deterioration test or a simulation analysis result.

4. The charge/discharge control device according to claim 1, wherein the deterioration factor includes at least one or more of a charging time that is a period during which a current value is positive, a discharging time that is a period during which the current value is negative, a battery average temperature, a cycle depth in which an increase/decrease amount of an SOC is calculated, an SOC upper limit value, and an SOC average value.

5. The charge/discharge control device according to claim 1, wherein the reference operation pattern and the reference deterioration amount are periodically updated based on an operation history and a charge/discharge pattern of a user in the past.

6. The charge/discharge control device according to claim 1, wherein a notification of an accumulation status of the deterioration factor and charge/discharge plan-related information such as a recommended EV connection time is performed through an in-vehicle screen or a smartphone owned by a driver.

7. A charge/discharge control method for controlling charge/discharge of a storage battery connected to a load, with a computer, the charge/discharge control method comprising: by the computer,
setting a reference operation pattern of charge/discharge of the storage battery and calculating a reference deterioration amount that is a deterioration amount of the storage battery in the reference operation pattern;
calculating an actual operation deterioration amount that is a deterioration amount of the storage battery in an actual operation pattern different from the reference operation pattern when charge/discharge of the storage battery is operated in the actual operation pattern;
calculating a deterioration amount difference that is a difference between the reference deterioration amount and the actual operation deterioration amount; and
calculating a contribution degree of each of a plurality of deterioration factors that are factors of deterioration of the storage battery based on the deterioration amount difference.

8. The charge/discharge control method according to claim 7, further comprising changing a subsequent actual operation pattern to avoid accumulation of a specific deterioration factor among the plurality of deterioration factors.
